(19) United States
(12) Patent Application Publication
(10) Pub. No.: US 2013/0187670 A1
(43) Pub. Date: Jul. 25, 2013

(54) CAPACITIVE SENSORS AND METHODS OF FABRICATION

(71) Applicants: Kevin Dooley, Blessington (IE); Lorraine Byrne, Dublin (IE); Graeme Scott, Maynooth County (IE); Vladek Kasperchik, Corvallis, OR (US)

(72) Inventors: Kevin Dooley, Blessington (IE); Lorraine Byrne, Dublin (IE); Graeme Scott, Maynooth County (IE); Vladek Kasperchik, Corvallis, OR (US)

(21) Appl. No.: 13/353,695

(22) Filed: Jan. 19, 2012

(51) Int. Cl. G01R 27/26; B32B 37/02; B32B 37/14

(52) U.S. Cl. 324/686; 156/250; 156/151

(57) ABSTRACT

Apparatus and methods related to capacitive sensors are provided. Metal walls are formed in an interdigitated pattern. A dielectric material corresponding to a selected analyte is deposited in contact with the metal walls thus defining a capacitive sensor. Exposure to the analyte causes the electrical capacitance to vary in accordance with intensity. Analyte detection or measurement, data acquisition, or other operations can be performed by way of the capacitive sensors of the present teachings.

### BACKGROUND

Specialized electrical capacitors can be used to sense physical variables such as humidity, gaseous compounds, and so on. Improvements to such capacitive sensors and their methods of construction are continuously sought after. The present teachings address the foregoing concerns.

### BRIEF DESCRIPTION OF THE DRAWINGS

The present embodiments will now be described, by way of example, with reference to the accompanying drawings, in which:

FIGS. 1A-1E collectively depict a sequence of fabricating a capacitive sensor device as contemplated under the present teachings;

FIG. 2 depicts an isometric-like view of an interdigitated capacitor;

FIG. 3 depicts a block diagram of a sensing device;

FIG. 4 depicts a table of illustrative capacitive sensor constituents and analytes;

FIG. 5 depicts a flow diagram of a method according to the present teachings.

### DETAILED DESCRIPTION

### Introduction

Apparatus and methods related to capacitive sensors and methods of their fabrication are provided. Metal walls are formed in an interdigitated pattern, the metal walls having substantially rectangular (i.e., non-sloping) cross-sectional form. A dielectric material corresponding to a selected analyte is deposited in contact with the metal walls, so as to define a capacitive sensor. Exposure to the analyte causes the electrical capacitance of the sensor to vary in accordance with concentration (or intensity) of the analyte. Analyte detection or measurement, data acquisition, or other operations can be performed by way of the capacitive sensors of the present teachings.

In one example, a method includes forming a sacrificial photocurable layer over a conductive material, and forming a durable photocurable layer over the sacrificial photocurable layer. The method also includes defining an interdigitated pattern through the sacrificial and durable photocurable layers such that the conductive material is exposed within the interdigitated pattern. The method further includes forming metal walls within the interdigitated pattern. The metal walls are defined by a substantially rectangular cross-section. The method also includes adhesively bonding an electrically non-conductive material to the metal walls and to the durable photocurable layer. The method also includes removing the conductive material, and removing a remainder of the sacrificial photocurable layer. The method further includes providing a dielectric material in contact with the interdigitated metal walls so as to define a capacitive sensor.

In another example, a capacitive sensor includes a plurality of first metal walls common to a first electrical node. The capacitive sensor also includes a plurality of second metal walls common to a second electrical node. The first metal walls and the second metal walls are arranged in an interdigitated pattern, each of the first and second metal walls having an about rectangular cross sectional form. The capacitive sensor further includes a dielectric material in contact with the first metal walls and the second metal walls. The dielectric is selected such that the capacitive sensor is characterized by an electrical capacitance that varies in accordance with an intensity of exposure to an analyte.

In yet another example, an apparatus includes a capacitive sensor including a pattern of interdigitated metal walls defining a first electrical node and a second electrical node. Each of the metal walls is defined by an about rectangular cross-sectional shape. The capacitive sensor is characterized by an electrical capacitance that varies in accordance with a concentration of an analyte. The apparatus also includes electronic circuitry coupled to the capacitive sensor. The electronic circuitry is configured to operate in accordance with sensed values of the electrical capacitance.

### Illustrative Fabrication Sequence

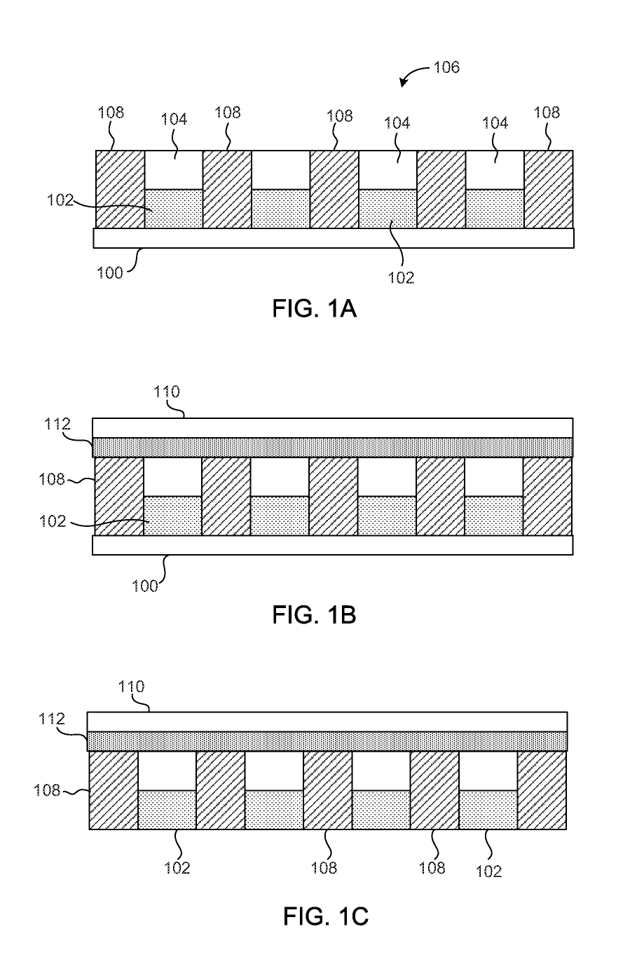

Reference is now made to FIGS. 1A-1E, which collectively depict a sequence of fabricating a capacitive sensing device. The sequence is illustrative and non-limiting with respect to the present teachings. Other sequences, materials, techniques, and resulting devices are also contemplated and can be used.

FIG. 1A depicts a conductive carrier or substrate 100. The substrate 100 can be formed from copper, aluminum or another electrically-conductive sheet material. A layer of photocurable resin material 102 is formed or deposited on the substrate 100. Non-limiting examples of the photocurable resin material 102 includes epoxy (SU-8, KMPR), poly(Methyl Methacrylate) (PMMA) (Ordyl P-50100 or Diaplate-132), Polydimethylsiloxane (PDMS) or phenol formaldehyde (Novolak) based resins. In one example, the photocurable material 102 is defined by a thickness in the range of about sub-micron scale to about 100 micrometers (i.e., 1 micrometer=1×10⁻⁶ meters). Other suitable thicknesses can also be used.

A layer of photocurable material 104 is formed over the photocurable material 102. The photocurable material 104 is chemically distinct from the photocurable material 102. In one example, the photocurable material 104 is defined by SU-8 photoresist, as available from MicroChem Corp., Newton, Mass., USA. Other suitable photocurable materials 104 can also be used.

The respective photocurable materials 102 and 104 are patterned and etched by way of one or more photolithography steps such that the conductive carrier 100 is exposed and an interdigitated pattern 106 is defined. Alternatively, embossing or imprint lithography can be used to define the pattern. Electroplating is used to form metallic walls 108 within the interdigitated pattern 106. In one example, the metallic walls are formed from nickel. Other non-limiting examples include copper, gold, silver or palladium. Other suitable metals or electrically-conductive materials can also be used. The electroplating results in metallic walls 108 having vertical sides that extend substantially orthogonally away from the conductive carrier 100. That is, the metallic walls 108 are defined by an about rectangular cross-sectional form and are substantially non-tapered in shape.

FIG. 1B depicts an electrically non-conductive material or sheet 110 bonded to the photocurable material 104 and the metallic walls 108 by way of an adhesive material 112. In one example, the non-conductive material (sheet) 110 is defined by polyethylene terephthalate (PET). Other suitable plastics or other electrically non-conductive (i.e., insulator) materials such as glass or silicon wafers can also be used.

FIG. 1C depicts the conductive carrier 100 having been removed. The metallic walls 108 and the respective photocurable materials 102 and 104 are now supported by bonded contact with the sheet 110.

FIG. 1D depicts the remaining portions of photocurable material 102 having been removed. A suitable solvent can be used in accordance with the particular photocurable material 102 to be removed. Alternatively, the material can be removed via plasma or reactive ion etching techniques. The metallic walls 108, defined by an interdigitated pattern, are now exposed on their respective side surfaces 114. Additionally, voids or channels 116 are defined between the metallic walls 108.

FIG. 1E depicts a dielectric material 118 filling the voids 116. In one example, the dielectric 118 is added or applied in a liquid phase by way of a jet printing process, and thereafter cures or changes phase to a solid or substantially solid phase. Other dielectric 118 application processes including spray, drop casting, screen printing or gravure printing can also be used, or change-of-phase scenarios, can also be used. The dielectric 118 is in contact with the side surfaces 114 of the metallic walls 108 and thus in continuous electrical contact therewith. A capacitive sensor (or device) 120 is thus defined.

The capacitive sensor 120 is characterized by an electrical capacitance that various in accordance with exposure to an analyte. More particularly, the metallic walls 108 define two distinct electrical nodes by virtue of their interdigitated configuration. These two electrical nodes are analogous or functionally equivalent to the respective “plates” of a capacitor. In turn, the dielectric material 118 selected so as to change in its dielectric constant in response to an intensity of exposure to particular compound or gaseous material.

Thus, various capacitive sensors 120 are contemplated that are sensitive to, for non-limiting example, humidity (water vapor), ammonia, carbon dioxide, hydrogen, sulfur dioxide, hydrogen sulfide, volatile hydrocarbons and so on. Examples of particular dielectrics 118 and the gaseous compounds to which they are respectively sensitive are provided hereinafter.

For example, base material for dielectric 118 can be one of the non-conductive metal or semi-metal oxides or complex metal oxides. Non-limiting examples of these oxides include titanium dioxide, alumina, indium oxide, silica, zinc oxide, barium titanate, and so on. The base dielectric oxide material is preferably used in the form of small particulate (average diameter 1-1000 nm). The surface of dielectric oxide particles is preferentially sensitized with a ligand treatment.

The purpose of the ligands attached to surface of the base dielectric oxide particles is to increase response of the capacitive sensor to presence of analyte gases or vapors in the analyzed air or other sample. Because of the small particle size surface area of the base dielectric oxide is very high and can retain large amount of the attached ligand. It is preferable that ligand is chemically attached to the dielectric oxide surface. Examples of the suitable ligands which can be attached to surfaces of a wide variety of dielectric oxide particles are functionalized silanes. The funtionalized silanes contain silanol Si(OH)3 or hydrolyzed alkoxysilane Si(OR)3 anchor group which can form bonds with the dielectric oxide surface. The functional silane molecule also contains a functional group which is directly or indirectly attached to the anchor group.

The purpose of the functional group is to interact with analyte present in gas phase and significantly change the dielectric constant of the dielectric material (118). For example, using metal oxide (SiO2 or TiO2) functionalized with hydrophilic polyether silane such as polyethyleneglycol alkoxysilane (—(CH2CH2O)ₙ—R functionality) one can produce dielectric material sensitive to changes in relative humidity. Switching ligand treatment to silanes with amine functionality would produce dielectric oxides with dielectric constant sensitized to presence of acidic gases such as sulfur dioxide or carbon dioxide, or others. Dielectrics including Ba, WO3, SnO2 or BiTiO3 are also contemplated. Other chemical species, compounds or embodiments can also be used.

In another example, the material for the dielectric consists of a non-conducting polymer such as polyvinyl alcohol or poly(methyl methacrylate). These materials swell in response to certain gases such as water vapor or ammonia which in turn alters the response of the capacitor through changes in the inter-electrode spacing.

### Illustrative Interdigitated Capacitor

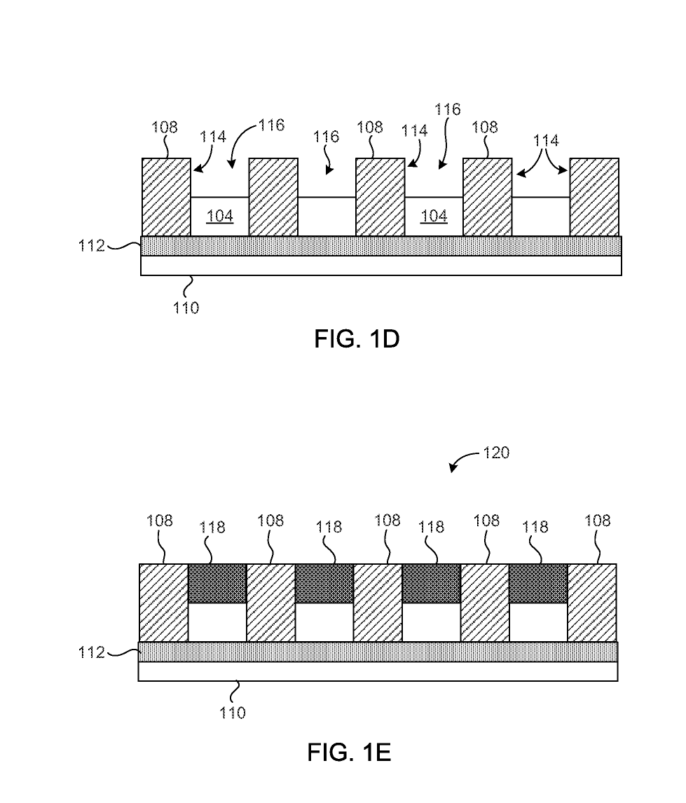

Attention is now turned to FIG. 2, which depicts an isometric-like view of an interdigitated capacitor (capacitor) 200. The capacitor 200 is illustrative and non-limiting in nature. Thus, other capacitors, devices, apparatus and systems are contemplated by the present teachings.

The capacitor 200 includes metallic walls 202 that are common to a first electrical node 204. The capacitor 200 also includes metallic walls 206 that are common to a second electrical node 208. The respective metallic walls 202 and 206 are interdigitated in their configuration and spaced apart such that the first and second electrical nodes 204 and 208, respectively, are not in electrically conductive contact. The metallic walls 202 and 206 are respectively characterized by mutually orthogonal height (H), width (W) and length (L) dimensions. In one example, each of the metallic walls 202 and 206 is defined by a height-to-width (i.e., H:W) ratio in the range of about 2:1 to about 20:1. Other suitable dimensional ratios can also be used.

The capacitor 200 also includes an electrically non-conductive substrate 210 supportive of the metallic walls 202 and 206, respectively. No dielectric material is depicted in the interest of clarity. However, it is to be understood that a dielectric (e.g., 118) can be provided between and in contact with the respective metallic walls 202 and 206. The capacitor 200 illustrates just one of any number of interdigitated configurations contemplated by the present teachings.

### Illustrative Device

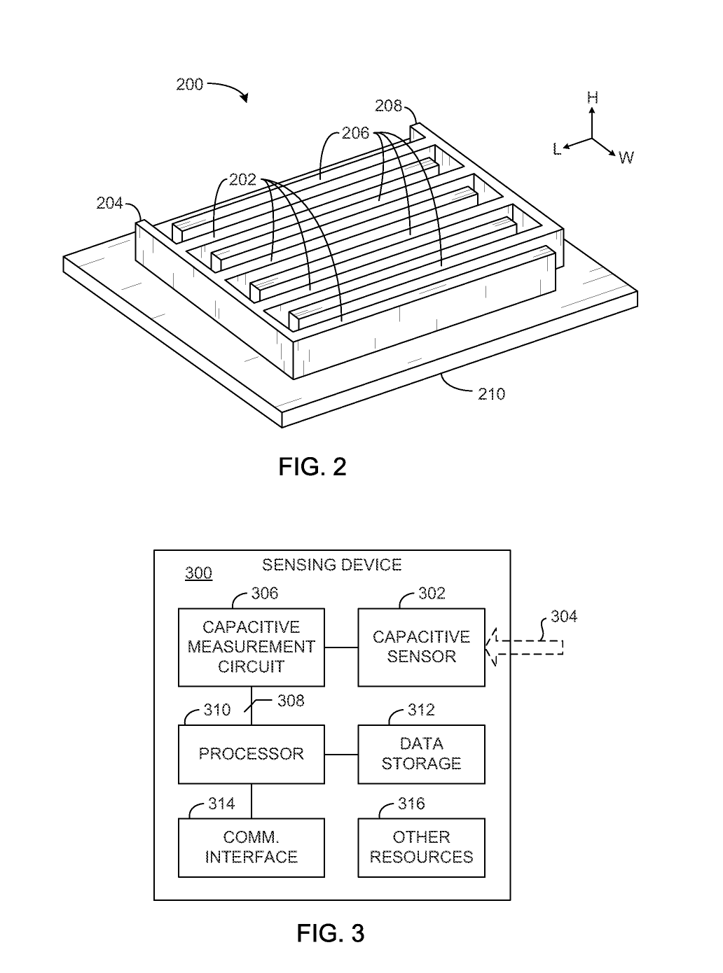

Reference is now directed to FIG. 3, which depicts a block diagram of a sensing device (device) 300 according to the present teachings. The device 300 is illustrative and non-limiting in nature. Thus, other devices, apparatus and systems are contemplated by the present teachings.

The device 300 includes a capacitive sensor 302. The capacitive sensor 302 can be defined by any capacitive sensor in accordance with the present teachings. Thus, the capacitive sensor 302 is characterized by an electrical capacitance (i.e., Farads) that varies in accordance with intensity of exposure to a particular analyte 304. Such an analyte 304 is gaseous or vaporous in nature and can be, for non-limiting example, water vapor, ammonia, carbon monoxide, and so on, in accordance with the dielectric of the capacitive sensor 302.

The device 300 also includes a capacitive measurement circuit (circuit) 306. The circuit 306 is coupled and configured to sense the instantaneous electrical capacitance of the capacitive sensor 302 and to provide a signal 308 corresponding thereto. The signal 308 can be analog or digital, or of any other suitable format. The circuit 306 can include any suitable constituency such as, for non-limiting example, a variable oscillator, a pulse generator, timing circuitry, and so on.

The device 300 also includes a processor 310 configured to operate in accordance with a machine-readable program code. The processor 310 is configured to control normal operations of the device 300 and to receive the signal 308 from the circuit 306. The processor 310 is coupled to data storage 312 of the device 310 and is configured to store digital values (i.e., discrete quantifications) representative of the signal 308. The data storage can be, without limitation, a non-volatile solid-state memory, a magnetic storage device, an optical storage device, and so on.

The device 300 also includes a communications interface (interface) 314. The interface 314 is coupled to the processor 310 and is configured to bidirectionally communicate or convey information and values between the device 300 and external entity or user. The interface 314 can include, without limitation, a user interface, network or wireless communications circuitry, an electronic display, a keypad, and so on. The device 300 further includes other resources 316. The other resources 316 can include any constituency needed for normal operations of the device 300 such as, for non-limiting example, a battery or power supply, a solar panel, an audible or visual annunciator, and so on.

In general, the device 300 is configured to sense an analyte 304 and to provide electrical signaling, visual or audible indications of the presence or concentration of the analyte 304. In one example, the device 300 provides a digital signal output in response to detecting carbon dioxide greater than a selectable threshold value. In another example, the device 300 senses and records relative humidity values at regular intervals. In still another example, the device 300 provides a visual indication of instantaneous of ammonia vapor concentration values. Other examples and analyte scenarios are also contemplated by the present teachings.

### Illustrative Table of Configurations

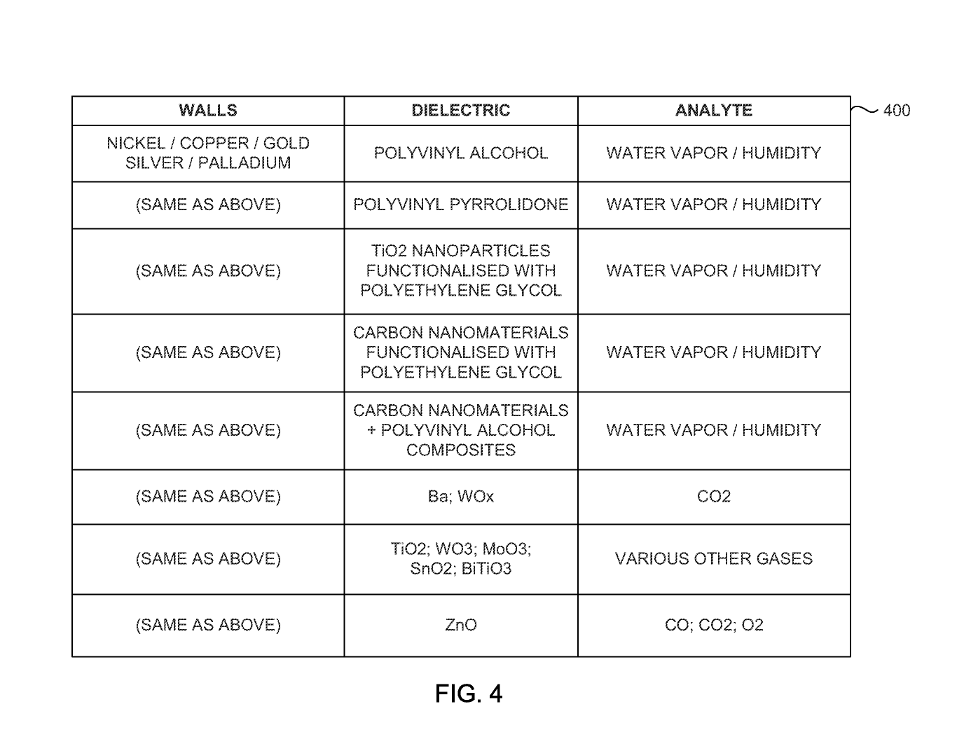

Attention is now directed to FIG. 4, which depicts a table 400 of illustrative constituents according to the present teachings. The table 400 is non-limiting in nature, and other constituents, configurations, materials and analytes, and can be defined and used according to the present teachings.

The table 400 includes illustrative and non-limiting materials for forming metallic walls (e.g., 108) of a capacitive sensor (e.g., 120) according the present teachings. Gold, silver, nickel, palladium or copper are just a few of the non-limiting materials that can be used. The table 400 also includes illustrative dielectric materials (e.g., 118) that can be used in accordance with the analyte to be sensed or measured.

In one example, a capacitive sensor includes metallic walls made of nickel and a dielectric material of polyvinyl alcohol configured for sensing water vapor (humidity). In another example, a capacitive sensor includes metallic walls made of copper and a dielectric material of zinc oxide configured for sensing carbon dioxide. Other illustrative configurations can also be used.

### Illustrative Method

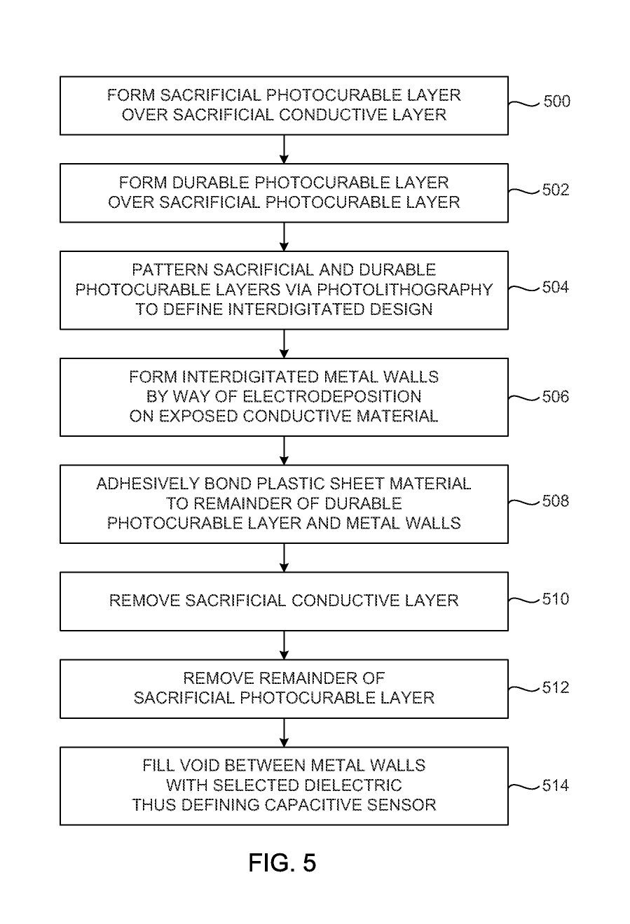

Reference is now made to FIG. 5, which depicts a flow diagram of a method according to another example of the present teachings. The method of FIG. 5 includes particular steps and proceeds in a particular order of execution. However, it is to be understood that other respective methods including other steps, omitting one or more of the depicted steps, or proceeding in other orders of execution can also be used. Thus, the method of FIG. 5 is illustrative and non-limiting with respect to the present teachings. Reference is also made to FIGS. 1A-1E and 2 in the interest of understanding the method of FIG. 5.

At 500, a sacrificial layer of photocurable material is formed over a sacrificial conductive layer. For purposes of a present example, a layer of photocurable material 102 is formed in continuous contact with a layer (sheet) of conductive material 100. In one instance, the sacrificial conductive layer 100 is copper. Other suitable materials can also be used.

At 502, a durable layer of photocurable material is formed over the sacrificial layer of photocurable material. In the present example, a layer of photocurable material 104 is formed in continuous contact with the sacrificial layer of photocurable material 102. The layer 104 is referred to “durable” because at least some of it will remain after all steps of the instant illustrative method are complete.

At 504, the sacrificial and durable photocurable layers are patterned by way of photolithography or embossing to defining an interdigitated design. In the present example, photolithography is used to form a pattern (i.e., channeling or voids) in the photocurable layers 102 and 104, respectively, such that the sacrificial conductive material 100 is exposed. The patterning defines a configuration characterized by two distinct interdigitated patterns.

At 506, metal walls are formed within the interdigitated pattern defined by way of electrodeposition on the exposed sacrificial conductive layer. In the present example, electrodeposition is used to form nickel walls 108 within the interdigitated pattern formed at step 504 above. The resulting interdigitated pattern of nickel walls 108 defines two electrical nodes (e.g., 204 and 208) supported on the sacrificial conductive layer 100. The metal walls are characterized by a substantially rectangular cross-section, without any appreciable taper in width from top to bottom.

At 508, a plastic sheet material is adhesively bonded to the other photocurable layer and the metal walls. In the present example, a plastic sheet 110 of PET is bonded by way of adhesive 112 to the remaining portion(s) of photocurable material 104 and the metal walls 108, opposite to the sacrificial conductive layer 100.

At 510, the sacrificial conductive layer is removed. In the present example, the sacrificial conductive material 100 is completely removed, thus exposing the metal walls 108 on one respective side and the remaining portion(s) of sacrificial photocurable material 102.

At 512, the remainder of the sacrificial photocurable material is removed. In the present example, the remaining photocurable 102 is removed by appropriate solvent. The resulting voids 116 expose respective side wall portions 114 of the metal walls 108.

At 514, the void between the metal walls is filled with a selected dielectric material such that a capacitive sensor is defined. In the present example, a dielectric 118 of (or including) zinc oxide is depositing into the void 116 by way of jet printing application. The dielectric 118 is in contact with the sides 114 of the metal walls 108 such that a capacitive sensor 120 is defined. The capacitive sensor 120 of the present illustration is characterized by an electrical capacitance that varies in accordance with a concentration of carbon dioxide to which the capacitive sensor 120 is exposed. The dielectric 118 is applied in a substantially liquid phase and cures (or hardens) to a substantially solid phase.

In general and without limitation, the present teachings contemplate capacitive sensors and methods of their fabrication. Two distinct layers of photocurable material are applied or formed over a conductive layer or sheet of material. The photocurable layers are then patterned using photolithography such that an interdigitated pattern is formed, exposing the conductive layer. The interdigitated pattern is characterized by substantially rectangular cross-sectional form, being without appreciable taper or slope.

Electrodeposition is then used to form metal walls within the interdigitated pattern. The metal walls collectively define two respective electrical nodes. The metal walls are characterized by side surfaces extending orthogonally away from the supporting conductive layer and having the same rectangular cross-section as the interdigitated patter in which they are formed.

The plastic or other non-conductive sheet is adhesively bonded to the metal walls and the remainder of one of the photocurable layers, on a side opposite the conductive layer. The conductive layer is then removed by solvent or other suitable means. A remainder of one of the layers of photocurable—referred to as a sacrificial layer—is removed and the resulting void is filled with a selected dielectric material. The resulting structure defines a capacitive sensor.

The dielectric is porous with respect to a particular analyte such the electrical capacitance of the sensor various in accordance with concentration exposure to that analyte. Non-limiting examples of analytes include carbon dioxide, ammonia, water vapor, nitrogen dioxide, and so on. The instantaneous capacitance of the capacitive sensor can be measured by appropriate electronic circuitry and digital or analog signal derived there from. Analyte detection or measuring instruments, gas alarms, humidity sensors and the like can be configured and constructed by way of capacitive sensors of the present teachings.

In general, the foregoing description is intended to be illustrative and not restrictive. Many embodiments and applications other than the examples provided would be apparent to those of skill in the art upon reading the above description. The scope of the invention should be determined, not with reference to the above description, but should instead be determined with reference to the appended claims, along with the full scope of equivalents to which such claims are entitled. It is anticipated and intended that future developments will occur in the arts discussed herein, and that the disclosed systems and methods will be incorporated into such future embodiments. In sum, it should be understood that the invention is capable of modification and variation and is limited only by the following claims.

What is claimed is:

1. A method, comprising:
forming a sacrificial photocurable layer over a conductive material;
forming a durable photocurable layer over the sacrificial photocurable layer;
defining an interdigitated patter through the sacrificial and durable photocurable layers such that the conductive material is exposed within the interdigitated pattern;
forming metal walls within the interdigitated patter, the metal walls defined by a substantially rectangular cross-section;
adhesively bonding an electrically non-conductive material to the metal walls and to the durable photocurable layer;
removing the conductive material;
removing a remainder of the sacrificial photocurable layer; and
providing a dielectric material in contact with the interdigitated metal walls so as to define a capacitive sensor.

2. The method according to claim 1, the forming the metal walls performed at least in part by way of electrodeposition.

3. The method according to claim 1, the metal walls including at least nickel, copper, silver, gold or palladium.

4. The method according to claim 1, the electrically non-conductive material including a plastic.

5. The method according to claim 1, the interdigitated pattern such that the metal walls define a first electrical node and a second electrical node distinct from the first electrical node.

6. The method according to claim 1, the metal walls defined by an average height-to-width aspect ratio in the range of about 2:1 to about 20:1.

7. The method according to claim 1, the dielectric changing phase from about fluid phase to about solid phase after the providing.

8. The method according to claim 1, the dielectric selected such that an electrical capacitance of the capacitive sensor varies in accordance with a concentration of a predetermined analyte.

9. The method according to claim 1, the providing the dielectric performed by way of a liquid deposition process.

10. A capacitive sensor, comprising:
a plurality of first metal walls common to a first electrical node;
a plurality of second metal walls common to a second electrical node, the first metal walls and the second metal walls arranged in an interdigitated pattern, each of the first and second metal walls having an about rectangular cross-sectional form; and
a dielectric material in contact with the first metal walls and the second metal walls, the dielectric selected such that the capacitive sensor is characterized by an electrical capacitance that varies in accordance with an intensity of exposure to an analyte.

11. The capacitive sensor according to claim 10, the dielectric material being about solid.

12. The capacitive sensor according to claim 10, the first metal walls and the second metal walls adhesively bonded to an electrically non-conductive substrate.

13. The capacitive sensor according to claim 10, the analyte including at least water vapor, ammonia, nitrogen dioxide, carbon monoxide, carbon dioxide, volatile hydrocarbons, sulfur dioxide, hydrogen, or hydrogen sulfide.

14. The capacitive sensor according to claim 10, at least some of the first and second metal walls defined by a height-to-width ratio in the range of about 2:1 to about 20:1.

15. An apparatus, comprising:
a capacitive sensor including a pattern of interdigitated metal walls defining a first electrical node and a second electrical node, each of the metal walls defined by an about rectangular cross-sectional shape, the capacitive sensor characterized by an electrical capacitance that varies in accordance with a concentration of an analyte; and
electronic circuitry coupled to the capacitive sensor and configured to operate in accordance with sensed values of the electrical capacitance.
